(19) United States
(12) Patent Application Publication
(10) Pub. No.: US 2025/0263830 A1
(43) Pub. Date: Aug. 21, 2025

(54) METHOD OF FORMING CARBON-BASED FILM AND FILM FORMING APPARATUS

(71) Applicant: Tokyo Electron Limited, Tokyo (JP)

(72) Inventors: Tadashi MITSUNARI, Nirasaki City (JP); Takahiro SHINDO, Tokyo (JP)

(21) Appl. No.: 19/046,860

(22) Filed: Feb. 6, 2025

(30) Foreign Application Priority Data
Feb. 16, 2024 (JP) 2024-022358

(51) Int. Cl. C23C 16/04; C23C 16/26; C23C 16/458; C23C 16/46; C23C 16/509; H01J 37/32; H01L 21/02

(52) U.S. Cl. CPC C23C 16/04; C23C 16/26; C23C 16/4583; C23C 16/46; C23C 16/509; H01L 21/02115; H01L 21/02274; H01J 37/32082; H01J 2237/332

(57) ABSTRACT

A method of forming a carbon-based film includes forming the carbon-based film on a substrate having a pattern. In the forming the carbon-based film, plasma is generated from a film-forming gas composed only of a hydrocarbon gas and a noble gas to selectively form the carbon-based film on a top of the pattern.

### CROSS-REFERENCE TO RELATED APPLICATION

This application is based upon and claims the benefit of priority from Japanese Patent Application No. 2024-022358, filed on Feb. 16, 2024, the entire contents of which are incorporated herein by reference.

### TECHNICAL FIELD

The present disclosure relates to a method of forming a carbon-based film and a film forming apparatus.

### BACKGROUND

In semiconductor devices, techniques are known for selectively forming a carbon-based film on the top of trenches or holes formed in a mask or etching target film, in order to realize more complex wiring shapes and fine wiring. For example, in the technique described in Patent Document 1, a carbon-based film is formed on the top of a trench formed in a base made of silicon. Specifically, a flowable film, which is an amorphous carbon polymer film, is primarily deposited on the bottom of the trench in the base. Then, the flowable film on the bottom is exposed to a nitrogen plasma, so that the flowable film on the bottom is etched while forming a gaseous CₓN_{y}H_{z} species from the flowable film. At this time, since the adhesion coefficient of the CₓN_{y}H_{z} species to the top of the trench where silicon is exposed is higher than that to the flowable film on the bottom, the CₓN_{y}H_{z} species are selectively redeposited on the top of the trench. As a result, a carbon-based film is selectively formed on the top of the trench.

Further, when performing plasma processing on a wafer on which semiconductor devices are formed, a technique is known for preventing a voltage of an upper electrode which faces a stage on which the wafer is placed from fluctuating significantly to the positive side, in order to reduce the impact input of ions from plasma onto the wafer. In this technique, a clamp circuit is provided between a radio frequency power supply and the upper electrode, so that the voltage waveform of the radio frequency power supply is shaped to restrain a positive voltage in a radio frequency voltage applied to the upper electrode by the clamp circuit (see, for example, Patent Document 2).

### PRIOR ART DOCUMENTS

### Patent Documents

Patent Document 1: Japanese laid-open publication No. 2021-019199

Patent Document 2: Japanese laid open publication No. 2022-018062

### SUMMARY

According to one embodiment of the present disclosure, there is provided a method of forming a carbon-based film including forming the carbon-based film on a substrate having a pattern. In the forming the carbon-based film, plasma is generated from a film-forming gas composed only of a hydrocarbon gas and a noble gas to selectively form the carbon-based film on a top of the pattern.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating a configuration of a film forming apparatus as one embodiment of the technique according to the present disclosure.

FIG. 2 is a diagram illustrating the voltage waveforms at an upper electrode of the film forming apparatus of FIG. 1 with a clamp circuit and at an upper electrode of a conventional film forming apparatus of FIG. 3 without a clamp circuit.

FIG. 3 is a cross-sectional view schematically illustrating a configuration of the conventional film forming apparatus without the clamp circuit.

FIG. 4 is a diagram illustrating the distribution of plasma in the film forming apparatus of FIG. 1.

FIGS. 5A and 5B are diagrams illustrating respective film formation shapes when performing film formation in the film forming apparatus of FIG. 1 and in the conventional film forming apparatus of FIG. 3.

FIGS. 6A and 6B are diagrams illustrating the effect of the presence or absence of a clamp circuit on the film formation shape of a carbon-based film.

FIG. 7 is a cross-sectional view schematically illustrating a configuration of a film forming apparatus as a modification of the embodiment of the technique according to the present disclosure.

FIG. 8 is a diagram illustrating the voltage waveform at the upper electrode when a pulsed negative DC voltage is applied from a DC power supply to the upper electrode.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the technique described in Patent Document 1, after depositing the flowable film on the bottom of the trench, the carbon-based film is redeposited on the top of the trench by exposure to the nitrogen plasma. Therefore, forming the carbon-based film on the top of the trench requires two steps, which deteriorates throughput. Further, in the technique described in Patent Document 1, as the redeposition of the carbon-based film on the top of the trench progresses, there is a risk of overhang of the carbon-based film occurring, which will block the trench.

In contrast, the technique according to the present disclosure improves throughput while preventing the occurrence of overhang of a carbon-based film when selectively forming the carbon-based film on the top of a pattern such as a trench or hole.

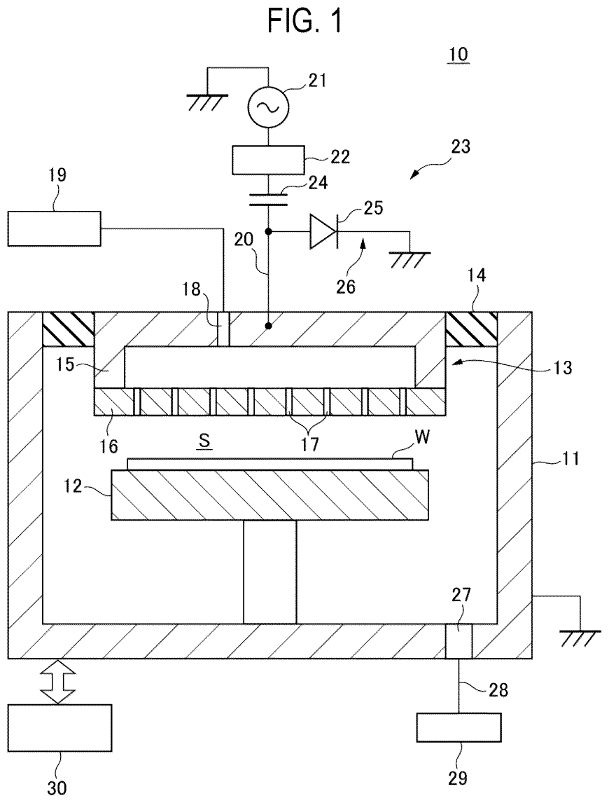

Hereinafter, one embodiment of the technique according to the present disclosure will be described with reference to the drawings. FIG. 1 is a cross-sectional view schematically illustrating a configuration of a film forming apparatus according to the present embodiment. The film forming apparatus is a capacitively coupled plasma processing apparatus that generates plasma from a film-forming gas as a processing gas to perform film formation. The film forming apparatus executes a method of forming a carbon-based film as one embodiment of the technique according to the present disclosure.

In FIG. 1, the film forming apparatus 10 includes an approximately cylindrical metallic chamber 11 (processing chamber), and the chamber 11 is grounded. A wafer W (substrate) is accommodated and a stage 12 on which the wafer W is placed is also arranged in the interior of the chamber 11.

The stage 12 is made of an insulator and includes a grounded lower electrode (not illustrated). In addition, the stage 12 may be made of a metal, thus also functioning as a lower electrode. A heater and a coolant passage (both not illustrated) are embedded within the stage 12. The heater generates heat upon receiving power supplied from the outside to heat the placed wafer W, and the coolant passage cools the placed wafer W by circulating a coolant supplied from the outside. In addition, to enhance the heat transfer between the stage 12 and the wafer W, a heat transfer gas is supplied between the stage 12 and the wafer W. Further, multiple lifting pins (not illustrated) are inserted through the stage 12 so as to be capable of protruding or retreating relative to an upper surface of the stage 12. The plurality of lifting pins are raised or lowered by a lifting mechanism (not illustrated) to transfer the wafer W to or from the stage 12.

An opening is formed at the top of the chamber 11, and a shower head 13 is fitted into the opening via an insulating material 14 so as to face the stage 12. The shower head 13 is made of a cylindrical metal member and functions as an upper electrode. In addition, only a portion of the shower head 13, rather than the entirety thereof, may be made of a metal, and that metal portion may function as an upper electrode. The shower head 13 includes a shower main body 15 having an opening at the bottom and a shower plate 16 provided to block the opening of the shower main body 15, with the internal space between them functioning as a gas diffusion space. Further, multiple gas discharge holes 17 are formed in the shower plate 16 to penetrate the shower plate 16 in the thickness direction. Furthermore, a gas introduction hole 18 is formed in the shower head 13, and a processing gas supplied from a gas supplier 19 to be described later is introduced into the gas diffusion space through the gas introduction hole 18. Then, the processing gas introduced into the gas diffusion space is diffused and discharged from each gas discharge hole 17 into the space (hereinafter referred to as “processing space”) S between the shower head 13 and the stage 12 in the interior of the chamber 11.

The film forming apparatus 10 further includes the gas supplier 19. The gas supplier 19 supplies multiple gases such as the processing gas and a purge gas. The gas supplier 19 includes multiple gas sources, flow-rate controllers, and opening/closing valves, and adjusts the flow rate of each gas according to the processing. In addition, in the present embodiment, a film-forming gas composed only of an acetylene (C₂H₂) gas (hydrocarbon gas) and an argon (Ar) gas (noble gas) is used as the processing gas supplied by the gas supplier 19.

A radio frequency power supply 21 is connected to the shower head 13 through a feeder 20. The radio frequency power supply 21 applies a radio frequency voltage with a frequency of 100 kHz to 60 MHz, for example, 450 kHz to the shower head 13. By applying the radio frequency voltage to the shower head 13, plasma is generated from the film-forming gas in the processing space S.

A matcher 22 is connected downstream of the radio frequency power supply 21 in the feeder 20. The matcher 22 matches the load impedance with the internal (or output) impedance of the radio frequency power supply 21. Furthermore, a clamp circuit 23 (voltage restrainer) is provided between the radio frequency power supply 21 in the feeder 20 and the shower head 13, specifically, downstream of the matcher 22 in the feeder 20.

The clamp circuit 23 includes a capacitor 24 provided downstream of the matcher 22 and a ground circuit 26 that branches from the feeder 20 downstream of the capacitor 24 and is grounded through a diode 25. The capacitor 24 has a sufficient capacitance to ensure a low impedance with respect to the radio frequency power supply 21.

The clamp circuit 23 allows a radio frequency current to pass through the diode 25 to the ground side when the radio frequency power supply 21 outputs a positive voltage (plus voltage) with the storage function of the capacitor 24 and the rectifying function of the diode 25 in the ground circuit 26. At this time, the radio frequency power output from the radio frequency power supply 21 is stored in the capacitor 24. This restrains the positive voltage in the radio frequency voltage applied to the shower head 13. On the other hand, when the radio frequency power supply 21 outputs a negative voltage (minus voltage), the diode 25 does not allow the radio frequency current to pass, preventing the radio frequency current from flowing to the ground side through the ground circuit 26. Then, at this time, the power output from the radio frequency power supply 21 and the power stored in the capacitor 24 are supplied to the shower head 13.

In addition, in the film forming apparatus 10, the clamp circuit 23 is provided as a circuit for restraining the positive voltage in the radio frequency voltage, but other types of circuits capable of restraining the positive voltage in the radio frequency voltage may be provided instead of the clamp circuit 23. Further, instead of the capacitor 24 in the clamp circuit 23, a blocking capacitor of the matcher 22 may store the radio frequency power output from the radio frequency power supply 21. In this case, it may be unnecessary to provide the capacitor 24 in the clamp circuit 23.

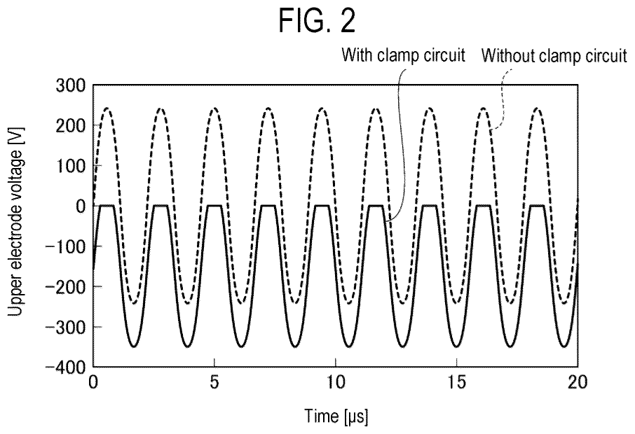

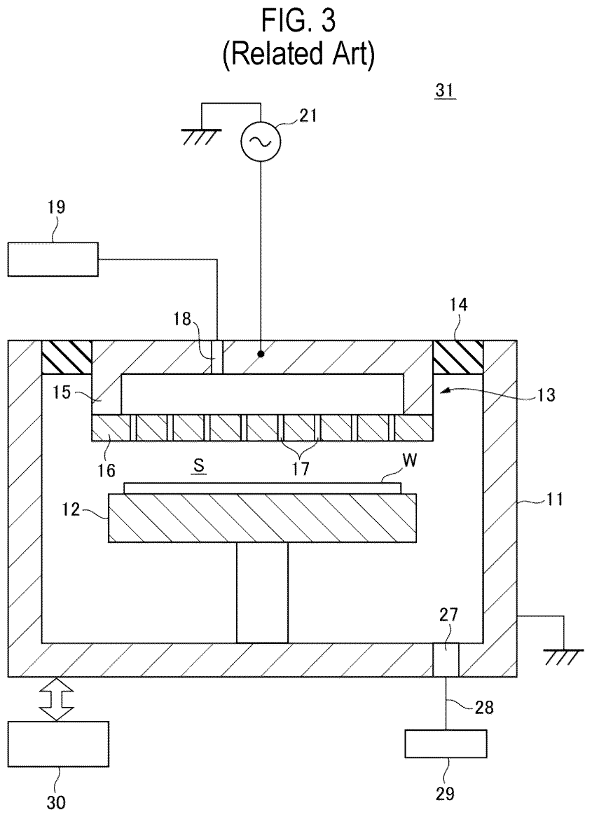

FIG. 2 is a diagram illustrating the voltage waveforms at the upper electrode (shower head 13) of the film forming apparatus 10 of FIG. 1 with the clamp circuit 23 and at an upper electrode of a conventional capacitively coupled plasma processing apparatus 31 without the clamp circuit 23 as illustrated in FIG. 3. In FIG. 2, the voltage waveform in the film forming apparatus 10 of FIG. 1 is represented by a solid line, while the voltage waveform in the conventional film forming apparatus 31 is represented by a broken line. In addition, the conventional capacitively coupled plasma processing apparatus 31 without the clamp circuit 23 will be hereinafter referred to as “conventional film forming apparatus 31.”

As illustrated in FIG. 2, in the conventional film forming apparatus 31, since the positive voltage is not restrained by the clamp circuit 23, the voltage of the upper electrode fluctuates significantly not only to the negative side but also to the positive side. On the other hand, in the film forming apparatus 10 of FIG. 1, since the positive voltage is restrained by the clamp circuit 23, the voltage of the upper electrode does not fluctuate significantly to the positive side. Then, in the capacitively coupled plasma processing apparatus, when the lower electrode is grounded, the plasma potential greatly depends on the potential of the upper electrode. Therefore, the film forming apparatus 10 may reduce the plasma potential compared to the conventional film forming apparatus 31. Further, ions in plasma are accelerated by a sheath voltage and are introduced into the wafer W. However, when the plasma potential is reduced, the absolute value of the sheath voltage (the difference between the plasma potential and the potential of the wafer W (stage 12)) generated in the processing space S becomes smaller, resulting in less acceleration of the ions. As a result, in the film forming apparatus 10 of FIG. 1, the ion energy imparted from the plasma to the wafer W placed on the stage 12 is reduced.

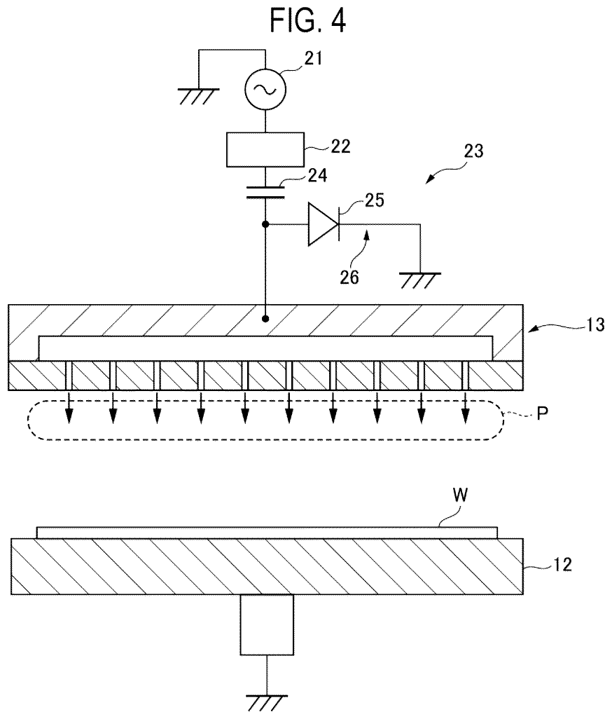

Further, in the film forming apparatus 10, as described above, since the voltage of the shower head 13 does not significantly fluctuate to the positive side, a high-density plasma P is generated mainly near the shower head 13 in the processing space S, as illustrated in FIG. 4. This allows the processing gas discharged from each gas discharge hole 17 of the shower head 13 to reliably pass through the high-density plasma P. As a result, the dissociation of the discharged processing gas is promoted by the high-density plasma P, resulting in the efficient generation of plasma and the generation of a large amount of ions and radicals.

Furthermore, in the film forming apparatus 10, an exhaust port 27 is provided at the bottom of the chamber 11, and an exhaust device 29 is connected to the exhaust port 27 through an exhaust pipe 28. The exhaust device 29 includes an automatic pressure control valve and a vacuum pump, and exhausts the interior of the chamber 11 to reduce the internal pressure while maintaining the interior of the chamber 11 at a desired vacuum level. Further, a loading/unloading port (not illustrated) for loading or unloading the wafer W is provided on a sidewall of the chamber 11. The loading/unloading port is opened or closed by a gate valve (not illustrated).

Furthermore, the film forming apparatus 10 includes a controller 30, and the controller 30 controls each component of the film forming apparatus 10. The controller 30 is a computer equipped with a processor, a memory, an input device, a display device, a signal input/output interface, and others. The memory of the controller 30, which is a non-transitory computer-readable storage medium, stores control programs and recipe data. When executing film formation in the film forming apparatus 10, the processor of the controller 30 executes a corresponding control program and controls each component of the film forming apparatus 10 based on the recipe data.

Specifically, the controller 30 controls the gas supplier 19 and the exhaust device 29 to adjust the internal pressure of the chamber 11, and controls the radio frequency power supply 21 to apply the radio frequency voltage to the shower head 13. Further, the controller 30 controls the gas supplier 19 to diffuse and introduce the film-forming gas to the interior of the chamber 11. At this time, the electric field generated by the radio frequency voltage applied to the shower head 13 excites each gas molecule of the film-forming gas to generate plasma. Film formation is performed on the wafer W by the plasma (film formation step).

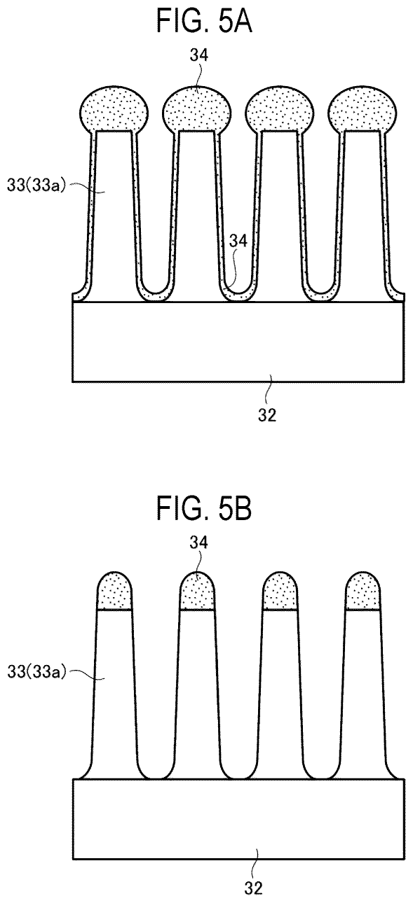

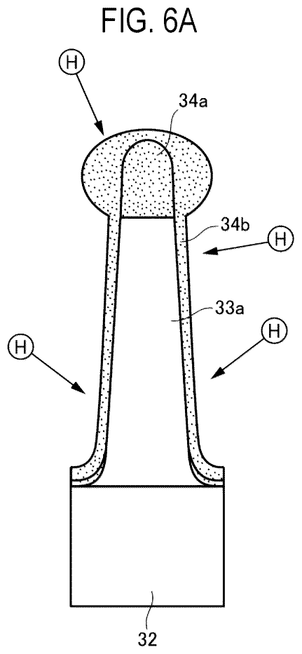

The inventors performed film formation on the wafer W using the film forming apparatus 10 of FIG. 1 and the conventional film forming apparatus 31 of FIG. 3. FIGS. 5A and 5B are diagrams illustrating respective film formation shapes when performing film formation in the film forming apparatus 10 of FIG. 1 and in the conventional film forming apparatus 31 of FIG. 3. In FIGS. 5A and 5B, enlarged partial cross-sectional views of an oxide layer 33 are illustrated, which is formed on a surface of the wafer W with a silicon base 32 and which has multiple trenches formed as a pattern. In addition, the oxide layer 33 serves as an insulating film and an underlayer for a carbon-based film 34 to be formed.

At this time, the inventors set the addition rate of acetylene gas in the film-forming gas to 6.25% (flow rate of 10 sccm) and the addition rate of argon gas to 93.75% (flow rate of 150 sccm) in either the film forming apparatus 10 of FIG. 1 or the conventional film forming apparatus 31 of FIG. 3. In addition, as described above, the film-forming gas in the present embodiment is composed only of acetylene and argon gases, and the addition rate of each gas represents the flow rate ratio of each gas to the total gas flow rate of the film-forming gas. Then, the internal pressure of the chamber 11 was set to 2 Torr, and radio frequency power of 500 W with a frequency of 450 kHz was supplied from the radio frequency power supply 21 to the shower head 13, generating plasma from the film-forming gas to perform film formation on the wafer W. Further, the gap between the shower head 13 and the stage 12 was set to 15 mm, and the temperature of the wafer W (actually the temperature of the stage 12) was set to 400 degrees C.

FIG. 5A illustrates the film formation shape of the carbon-based film 34 when film formation was performed in the conventional film forming apparatus 31 of FIG. 3, while FIG. 5B illustrates the film formation shape of the carbon-based film 34 when film formation was performed in the film forming apparatus 10 of FIG. 1.

First, when film formation was performed in the conventional film forming apparatus 31, it was confirmed that the carbon-based film 34 was formed to overhang toward each trench on the top of each fin 33a (top of the pattern) fitted into the trench of the oxide layer 33. Further, it was confirmed that the carbon-based film 34 was also formed inside the trench, thus adhering to a side surface of the fin 33a and the bottom of the trench. In other words, it was confirmed that the carbon-based film 34, which is not suitable for a selective formation on the top of the fin 33a, was formed.

On the other hand, when film formation was performed in the film forming apparatus 10, it was confirmed that the carbon-based film 34 was formed only on the top of the fin 33a without any overhang of the carbon-based film 34 toward the trench, and the carbon-based film 34 was hardly formed inside the trench. In other words, it was confirmed that the carbon-based film 34, which is suitable for a selective formation on the top of the fin 33a, was formed.

It was found from the confirmation results illustrated in FIGS. 5A and 5B that by providing the clamp circuit 23, the overhang of the carbon-based film 34 formed on the top of the fin 33a is reduced, and the formation of the carbon-based film 34 inside the trench is prevented. The inventors have inferred the following mechanism as the reason for this phenomenon.

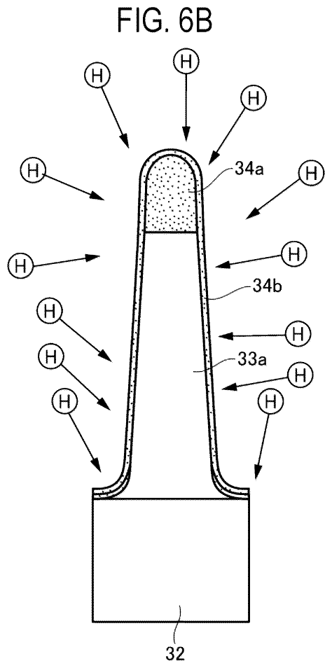

FIGS. 6A and 6B are diagrams illustrating the effect of the presence or absence of the clamp circuit 23 on the film formation shape of the carbon-based film 34.

First, the film formation shape in the conventional film forming apparatus 31 without the clamp circuit 23 as illustrated in FIG. 6A will be described.

In the conventional film forming apparatus 31 without the clamp circuit 23, since the voltage of the shower head 13 fluctuates significantly to the positive side, plasma is not generated mainly near the shower head 13, but instead is almost evenly distributed in the processing space S. In other words, the plasma is also present near the wafer W, meaning that hydrocarbon ions and hydrocarbon radicals included in the plasma generated from the acetylene gas, which is the main factor in the formation of the carbon-based film 34, is also present near the wafer W.

Here, hydrocarbon radicals are highly isotropic and adhere to the fin 33a of the oxide layer 33 from all directions. Therefore, in the conventional film forming apparatus 31, the carbon-based film 34 derived from hydrocarbon radicals adhere not only to the top of the fin 33a, but also to the side surface of the fin 33a and the bottom of the trench. On the other hand, hydrocarbon ions are highly anisotropic and adhere approximately vertically to the fin 33a of the oxide layer 33. Therefore, in the conventional film forming apparatus 31, the carbon-based film 34 derived from hydrocarbon ions adhere so as to be approximately vertically deposited on the top of the fin 33a.

In other words, not only the carbon-based film 34 derived from highly anisotropic hydrocarbon ions but also the carbon-based film 34 derived from highly isotropic hydrocarbon radicals adhere to the top of the fin 33a, resulting in the carbon-based film 34 overhanging toward the trench. In addition, for ease of understanding, in FIG. 6A and FIG. 6B to be described later, the carbon-based film derived from hydrocarbon ions is designated by reference numeral 34a, and the carbon-based film derived from hydrocarbon radicals is designated by reference numeral 34b. However, in reality, the carbon-based film 34a derived from hydrocarbon ions and the carbon-based film 34b derived from hydrocarbon radicals are mixed with each other to form the carbon-based film 34.

Further, the carbon-based film 34 is isotropically etched by hydrogen radicals contained in a hydrogen plasma. In the present embodiment, it is considered that when plasma is generated from an acetylene gas, a hydrogen plasma is generated from a part of the acetylene gas. Then, as described above, in the conventional film forming apparatus 31, the plasma is not generated mainly near the shower head 13 but is almost evenly distributed in the processing space S, which does not cause the generation of high-density plasma. Therefore, the dissociation of acetylene gas contained in the film-forming gas introduced into the processing space S does not progress significantly, resulting in less generation of hydrogen plasma. Thereby, few hydrogen radicals (designated by “H” in the drawing, the same in FIG. 6B) are present near the wafer W, and etching of the carbon-based film 34 by the hydrogen radicals also does not progress.

For the above reasons, in the conventional film forming apparatus 31, it was inferred that the carbon-based film 34 adheres to the side surface of the fin 33a and the bottom of the trench and the carbon-based film 34 overhangs toward the trench on the top of the fin 33a.

Next, the film formation shape in the film forming apparatus 10 with the clamp circuit 23 as illustrated in FIG. 6B will be described.

In the film forming apparatus 10 with the clamp circuit 23, as described above, the high-density plasma P is generated mainly near the shower head 13. In other words, the high-density plasma P is almost absent near the wafer W, resulting in a lower presence of hydrocarbon radicals contained in the plasma generated from the acetylene gas near the wafer W. Therefore, in the film forming apparatus 10, the carbon-based film 34b derived from hydrocarbon radicals does not adhere significantly not only to the top of the fin 33a, but also to the side surface of the fin 33a and the bottom of the trench.

Meanwhile, in the film forming apparatus 10, since the sheath voltage is generated in the processing space S although the absolute value thereof is smaller compared to the conventional film forming apparatus 31, hydrocarbon ions are accelerated toward the wafer W. In other words, hydrocarbon ions reach the wafer W even in the absence of the high-density plasma P near the wafer W. This progresses the formation of the carbon-based film 34 on the wafer W, which is primarily driven by highly anisotropic hydrocarbon ions. As a result, the carbon-based film 34a derived from hydrocarbon ions grows so as to be deposited approximately vertically on the top of the fin 33a.

Further, as described above, in the film forming apparatus 10, the high-density plasma P is generated mainly near the shower head 13. Therefore, the film-forming gas discharged from the shower head 13 reliably passes through the high-density plasma P, promoting the dissociation of acetylene gas contained in the film-forming gas and generating a large amount of hydrogen plasma. Then, since hydrogen radicals are lighter than hydrocarbon radicals and travel farther, many hydrogen radicals are present near the wafer W, which progresses the etching of the carbon-based film 34 by the hydrogen radicals. At this time, the etching by hydrogen radicals progresses isotropically, removing most of the carbon-based film 34b derived from hydrocarbon radicals that adheres slightly to the side surface of the fin 33a and the bottom of the trench. Further, the overhang of the carbon-based film 34 formed on the top of the fin 33a is also removed by etching from hydrogen radicals.

For the above reasons, it is inferred that, in the film forming apparatus 10 with the clamp circuit 23, the carbon-based film 34 almost does not adhere to the side surface of the fin 33a and the bottom of the trench, and the carbon-based film 34 on the top of the fin 33a does not overhang toward the trench.

In other words, according to the present embodiment, in the film forming apparatus 10 with the clamp circuit 23, the film-forming gas composed only of acetylene and argon gases is used to enable the formation of the non-overhanging carbon-based film 34 on the top of the fin 33a. Further, it almost prevents the adhesion of the carbon-based film 34 to the side surface of the fin 33a and the bottom of the trench. In other words, in the film forming apparatus 10 with the clamp circuit 23, there is no need to add a hydrogen gas to the film-forming gas, in order to promote etching by hydrogen radicals when forming the non-overhanging carbon-based film 34 on the top of the fin 33a.

Furthermore, according to the present embodiment, in the film forming apparatus 10 with the clamp circuit 23, simply generating plasma from the film-forming gas composed only of acetylene and argon gases enables the formation of the non-overhanging carbon-based film 34 on the top of the fin 33a. In other words, the non-overhanging carbon-based film 34 can be formed on the top of the fin 33a in a single step. Accordingly, when selectively forming the carbon-based film 34 on the top of the trench, it is possible to prevent the occurrence of the overhang of the carbon-based film 34 while improving throughput.

Further, when forming a carbon-based film in the film forming apparatus 10, increasing the addition rate of acetylene gas in the film-forming gas increases the amount of hydrocarbon radicals. At this time, even if the high-density plasma P is generated mainly near the shower head 13, the probability of hydrocarbon radicals being present near the wafer W increases. As a result, it is considered that the carbon-based film 34b derived from hydrocarbon radicals adhere to the side surface of the fin 33a and the bottom of the trench, making it likely that the carbon-based film 34 on the top of the fin 33a will overhang toward the trench. Therefore, to prevent the overhang of the carbon-based film 34 on the top of the fin 33a, there is an upper limit for the addition rate of acetylene gas in the film-forming gas. For example, it is desirable to set the addition rate of acetylene gas to be equal to or less than 10%.

Furthermore, when forming the carbon-based film in the film formation apparatus 10, lowering the temperature of the wafer W decreases the atmosphere temperature near the wafer W. The probability of hydrocarbon radicals adhering increases at the lower atmosphere temperature. Thus, not only does the carbon-based film 34a derived from hydrocarbon ions grows anisotropically on the top of the fin 33a, but the carbon-based film 34b derived from hydrocarbon radicals grows isotropically on the top of the fin 33a. As a result, it is considered that the carbon-based film 34 on the top of the fin 33a is likely to overhang toward the trench.

Therefore, to prevent the overhang of the carbon-based film 34 on the top of the fin 33a, there is a lower limit for the temperature of the wafer W (in reality, the temperature of the stage 12). For example, it is desirable to set the temperature of the wafer W to be higher than 200 degrees C., and more particularly, to be equal to or greater than 300 degrees C.

Further, when forming a carbon-based film in the film forming apparatus 10, increasing the internal pressure of the chamber 11 deactivates hydrocarbon ions, making it difficult for the hydrocarbon ions to reach the wafer W. Thus, it is considered that the carbon-based film 34a derived from hydrocarbon ions becomes difficult to grow on the top of the fin 33a, whereby the selective formation of the carbon-based film 34 does not occur on the top of the fin 33a. Therefore, to selectively form the carbon-based film 34 on the top of the fin 33a, there is an upper limit for the internal pressure of the chamber 11. For example, it is desirable to set the internal pressure of the chamber 11 to be equal to or less than 2 Torr.

In addition, in the film forming apparatus 10, it is also conceivable to connect the clamp circuit 23 to the lower electrode of the stage 12, rather than the shower head 13, while grounding the shower head 13 in a state where the orientation of the diode 25 is reversed. In this case as well, the plasma potential may be reduced, thereby decreasing the absolute value of the sheath voltage.

However, in this case, it is considered that the potential of the lower electrode becomes positive, causing a significant flow of electrons in the plasma toward the lower electrode, which leads to a local increase in electron density near the stage 12, potentially causing abnormal discharge near the wafer W. Therefore, it is not desirable to connect the clamp circuit 23 to the lower electrode.

While the preferred embodiments of the present disclosure have been described above, the present disclosure is not limited to the above-described embodiments, and various modifications and changes can be made within the scope of the spirit of the present disclosure.

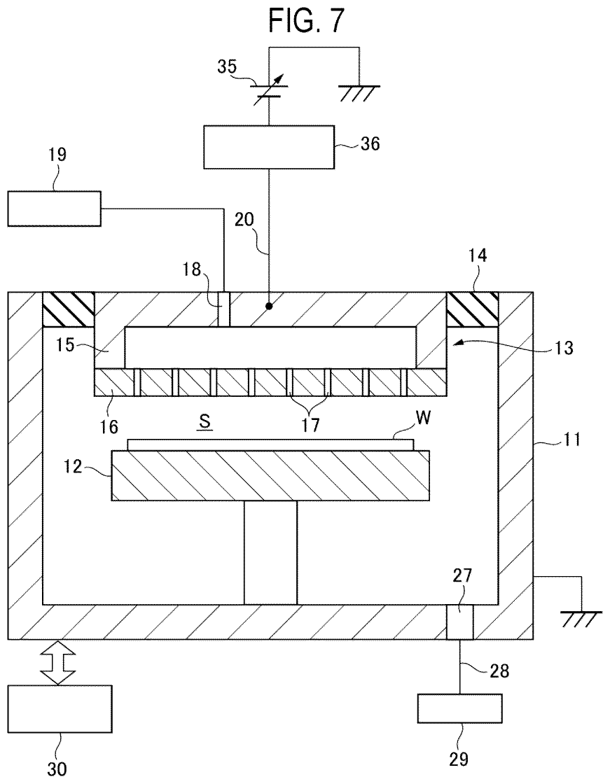

For example, in the preferred embodiments of the present disclosure, the clamp circuit 23 was provided as a circuit to restrain the positive voltage in the radio frequency voltage. However, as described above, instead of the clamp circuit 23, another type of circuit capable of restraining the positive voltage in the radio frequency voltage may be provided. For example, a circuit that applies a pulsed negative DC voltage to the upper electrode (shower head 13) may be provided. In this case, as illustrated in FIG. 7, a direct current (DC) power supply 35 is connected to the shower head 13 through the feeder 20, and the DC power supply 35 applies a pulsed negative DC voltage to the shower head 13. Further, a pulsing unit 36 is connected downstream of the DC power supply 35 in the feeder 20.

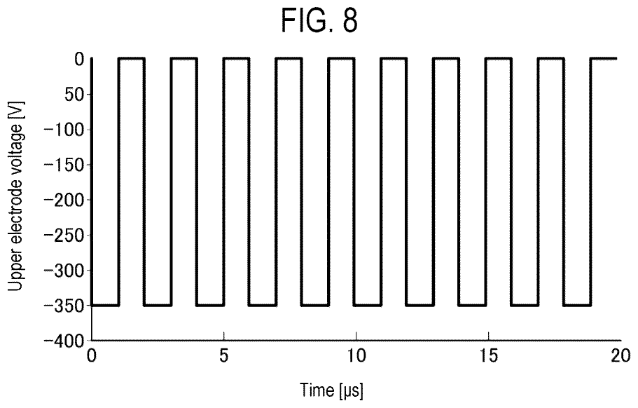

FIG. 8 is a diagram illustrating the voltage waveform at the upper electrode when a pulsed negative DC voltage is applied from the DC power supply 35 to the upper electrode. As illustrated in FIG. 8, when the pulsed negative DC voltage is applied to the upper electrode, the voltage of the upper electrode does not fluctuate to the positive side, allowing the plasma potential to be reduced. This makes it possible to reduce the absolute value of the sheath voltage generated in the processing space S, and similarly to when the clamp circuit 23 is provided, the ion energy imparted from the plasma to the wafer W placed on the stage 12 may be reduced.

Further, in the preferred embodiments of the present disclosure, film formation was performed on the wafer W in which multiple trenches are formed as a pattern, but the pattern is not limited to the trenches. For example, the pattern may include via holes, and in this case, the carbon-based film is formed on the top of a wall between respective via holes.

Further, in the preferred embodiments of the present disclosure, the carbon-based film 34 was formed on the oxide layer 33, but they are also applicable when selectively forming a carbon-based film on the top of a protrusion or fin of a metal layer such as a wiring layer.

Furthermore, in the preferred embodiments of the present disclosure, a hydrocarbon gas (acetylene gas) was used to selectively form a carbon-based film on the top of the fin 33a. However, other hydrogen compound gases may be used instead of the hydrocarbon gas. For example, a silane gas, which is a silicon hydrogen compound gas, or borane gas, which is a boron hydrogen compound gas, may be used.

When using a film-forming gas composed only of silane and argon gases and performing film formation on the wafer W with the film forming apparatus 10, a silicon-based film that does not overhang toward the trench or via hole may be selectively formed on the top of the fin. Further, when using a film-forming gas composed only of borane and argon gases and performing film formation on the wafer W with the film forming apparatus 10, a boron-based film that does not overhang toward the trench or via hole may be selectively formed on the top of the fin.

Further, the noble gas contained in the film-forming gas is not limited to the argon gas, and other noble gases, such as xenon (Xe) gas, may also be used.

According to the technique of the present disclosure, it is possible to improve throughput while preventing the occurrence of overhang of a carbon-based film when selectively forming the carbon-based film on the top of a pattern such as a trench or hole.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a carbon-based film, comprising forming the carbon-based film on a substrate having a pattern,
wherein, in the forming the carbon-based film, plasma is generated from a film-forming gas composed only of a hydrocarbon gas and a noble gas to selectively form the carbon-based film on a top of the pattern.

2. The method of claim 1, wherein in the forming the carbon-based film, the substrate is accommodated in a processing chamber with a depressurized interior and is placed on a stage disposed in the interior of the processing chamber, the plasma is generated from the film-forming gas in the interior of the processing chamber, and a positive voltage in a high frequency voltage applied to an upper electrode facing the stage is restrained.

3. The method of claim 1, wherein the hydrocarbon gas is an acetylene gas.

4. The method of claim 2, wherein the hydrocarbon gas is an acetylene gas.

5. The method of claim 1, wherein the noble gas is an argon gas.

6. The method of claim 2, wherein the noble gas is an argon gas.

7. The method of claim 1, wherein, in the forming the carbon-based film, the substrate is set to a temperature higher than 200 degrees C.

8. The method of claim 2, wherein, in the forming the carbon-based film, the substrate is set to a temperature higher than 200 degrees C.

9. The method of claim 7, wherein, in the forming the carbon-based film, the substrate is set to a temperature equal to or greater than 300 degrees C.

10. The method of claim 1, wherein an addition rate of the hydrocarbon gas in the film-forming gas is equal to or less than 10%.

11. The method of claim 2, wherein an addition rate of the hydrocarbon gas in the film-forming gas is equal to or less than 10%.

12. The method of claim 2, wherein, in the forming the carbon-based film, the processing chamber is set to an internal pressure equal to or less than 2 Torr.

13. A film forming apparatus comprising a processing chamber with a depressurized interior,
wherein a substrate having a pattern is accommodated in the interior of the processing chamber, and plasma is generated from a film-forming gas composed only of a hydrocarbon gas and a noble gas in the interior of the processing chamber to selectively form a carbon-based film on a top of the pattern.

14. The film forming apparatus of claim 13, further comprising:
a stage disposed in the interior of the processing chamber to place the substrate thereon;
an upper electrode facing the stage;
a radio frequency power supply configured to apply a radio frequency voltage for generation of the plasma to the upper electrode; and
a voltage restrainer configured to restrain a positive voltage in the applied radio frequency voltage.
